(19) United States
(12) Patent Application Publication
(10) Pub. No.: US 2025/0221281 A1
(43) Pub. Date: Jul. 3, 2025

(54) DISPLAY DEVICE

(71) Applicant: Japan Display Inc., Tokyo (JP)

(72) Inventors: Toshiharu MATSUSHIMA, TOKYO (JP); Yuji MAEDE, TOKYO (JP); Junko NAGASAWA, TOKYO (JP)

(73) Assignee: Japan Display Inc., Tokyo (JP)

(21) Appl. No.: 19/002,781

(22) Filed: Dec. 27, 2024

(30) Foreign Application Priority Data
Dec. 27, 2023 (JP) 2023-221236

(51) Int. Cl. H10K 59/80; H10K 59/35; H10K 59/38

(52) U.S. Cl. CPC H10K 59/879; H10K 59/352; H10K 59/353; H10K 59/38

(57) ABSTRACT

According to one embodiment, a display device comprises a substrate, a first light emitting element and a second light emitting element that are adjacent to each other in a first direction, a lower portion surrounding each of the first light emitting element and the second light emitting element, an upper portion provided on the lower portion, and a plurality of lenses having convex shapes projecting toward a side opposite to the substrate. The upper portion includes a first aperture overlapping the first light emitting element and a second aperture overlapping the second light emitting element. The plurality of lenses include a first lens overlapping the first aperture and the second aperture.

### CROSS-REFERENCE TO RELATED APPLICATIONS

This application is based upon and claims the benefit of priority from Japanese Patent Application No. 2023-221236, filed Dec. 27, 2023, the entire contents of which are incorporated herein by reference.

### FIELD

Embodiments described herein relate generally to a display device.

### BACKGROUND

Recently, various types of display devices have been proposed. For example, in display devices mounted on a vehicle such as automobiles, a viewing angle control is required in which different images are visually recognizable from a driver seat side and from a passenger seat side, respectively.

### BRIEF DESCRIPTION OF THE DRAWINGS

FIG. 1 is diagram showing a configuration example of a display device of a present embodiment.

FIG. 2 is a schematic plan view showing an example of a layout of subpixels.

FIG. 3 is a plan view showing an example of a layout of apertures and lenses.

FIG. 4 is a cross-sectional view showing a

configuration example of the display device along line A-A′ in FIG. 3.

FIG. 5 is a schematic plan view showing an example of a layout of the apertures.

FIG. 6 is a diagram for explaining effects of the present embodiment.

FIG. 7 is a diagram showing the display device of the present embodiment that is mounted on a vehicle-mounted device.

FIG. 8 is a diagram showing the display device of the present embodiment that is mounted on a vehicle-mounted device.

FIG. 9 is a diagram showing the display device of the present embodiment that is mounted on a vehicle-mounted device.

FIG. 10 is a schematic plan view showing another example of the layout of the apertures shown in FIG. 5.

FIG. 11 is a cross-sectional view showing another configuration example of the display device along line A-A′ in FIG. 3.

FIG. 12 is a cross-sectional view showing still another configuration example of the display device along line A-A′ in FIG. 3.

FIG. 13 is a cross-sectional view showing still another configuration example of the display device along line A-A′ in FIG. 3.

FIG. 14 is a schematic plan view showing another example of the layout of the apertures.

FIG. 15 is a schematic plan view showing another example of the layout of the apertures shown in FIG. 14.

FIG. 16 is a schematic plan view showing still another example of the layout of the apertures.

FIG. 17 is a schematic plan view showing still another example of the layout of the apertures shown in FIG. 16.

FIG. 18A is a plan view showing another example of the layout of the apertures and lenses.

FIG. 18B is a cross-sectional view showing a configuration example of the display device along line B-B′ and line C-C′ in FIG. 18A.

FIG. 19 is a schematic plan view showing still another example of the layout of the apertures.

FIG. 20 is a schematic plan view showing another example of the layout of the apertures shown in FIG. 19.

FIG. 21 is a schematic plan view showing another example of the layout of the subpixels.

FIG. 22 is a plan view showing another example of the layout of the apertures and lenses.

FIG. 23 is a schematic plan view showing an example of a layout of the apertures.

FIG. 24 is a diagram for explaining effects of the present embodiment.

FIG. 25 is a diagram showing the display device of the present embodiment that is mounted on a vehicle-mounted device.

FIG. 26 is a diagram showing the display device of the present embodiment that is mounted on a vehicle-mounted device.

FIG. 27 is a diagram showing the display device of the present embodiment that is mounted on a vehicle-mounted device.

FIG. 28 is a schematic plan view showing another example of the layout of the apertures shown in FIG. 23.

FIG. 29 is a schematic plan view showing another example of the layout of the apertures.

FIG. 30 is a schematic plan view showing another example of the layout of the apertures shown in FIG. 29.

### DETAILED DESCRIPTION

In general, according to one embodiment, a display device comprises: a substrate; a first light emitting element and a second light emitting element that are adjacent to each other in a first direction; a lower portion surrounding each of the first light emitting element and the second light emitting element; an upper portion provided on the lower portion; and a plurality of lenses having convex shapes projecting toward a side opposite to the substrate. The upper portion includes: a first aperture overlapping the first light emitting element and surrounded by an edge portion projecting relative to a side surface of the lower portion; and a second aperture overlapping the second light emitting element and surrounded by the edge portion projecting relative to the side surface of the lower portion. The plurality of lenses include a first lens overlapping the first aperture and the second aperture.

Embodiments described herein can provide a display device capable of limiting viewing angles.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction along the X-axis is referred to as a first direction X, a direction along the Y-axis is referred to as a second direction Y, and a direction along the Z-axis is referred to as a third direction Z. A plan view is defined as appearance when various types of elements are viewed parallel to the third direction Z.

The display device of the present embodiment is an organic electroluminescent display device comprising an organic light emitting diode (OLED) as a display element, and can be mounted on televisions, personal computers, vehicle-mounted devices, tablet terminals, smartphones, mobile phones, and the like.

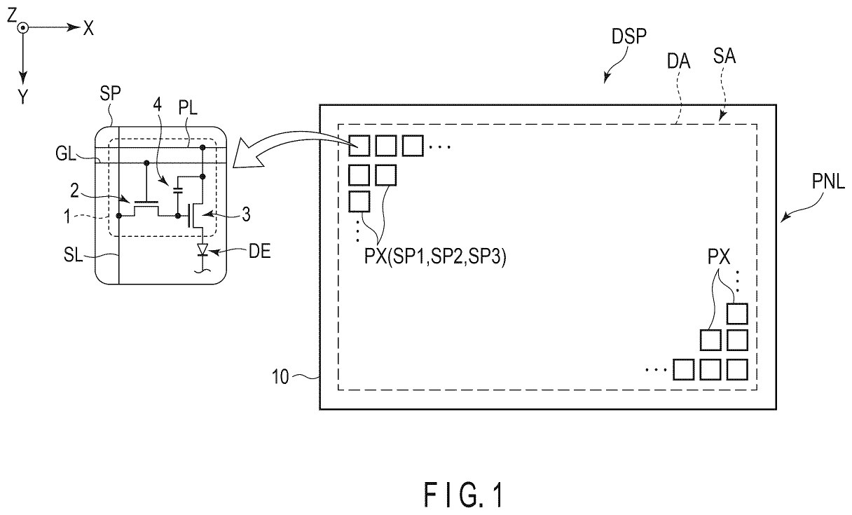

FIG. 1 is diagram showing a configuration example of a display device of a present embodiment. The display device DSP comprises a display panel PNL including a display area DA which displays an image and a surrounding area SA located on an external side relative to the display area DA on an insulating substrate 10. The substrate 10 may be glass or a resinous film having flexibility.

In FIG. 1, the substrate 10 has a rectangular shape having long sides parallel to the first direction X in plan view. The shape of the substrate 10 in a plan view is not limited to this example and may be another shape such as a rectangular shape having long sides parallel to the second direction Y, a square shape, a circular shape, or an elliptic shape.

The display area DA comprises a plurality of pixels PX arranged in a matrix in the first direction X and the second direction Y. Each pixel PX includes a plurality of subpixels SP. As an example, each pixel PX includes a subpixel SP1 which exhibits a first color, a subpixel SP2 which exhibits a second color, and a subpixel SP3 which exhibits a third color. The first, second, and third colors are colors different from each other. Each pixel PX may include a subpixel SP which exhibits another color such as white in addition to the subpixels SP1, SP2, and SP3 or instead of one of the subpixels SP1, SP2, and SP3.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A gate electrode of the pixel switch 2 is connected to a scanning line GL. Either a source electrode or a drain electrode of the pixel switch 2 is connected to a signal line SL. The other is connected to a gate electrode of the drive transistor 3 and the capacitor 4. In the drive transistor 3, one of the source electrode and the drain electrode is connected to a power line PL and the capacitor 4. The other is connected to the anode of the display element DE.

The configuration of the pixel circuit 1 is not limited to the example shown in the figure. For example, the pixel circuit 1 may comprise more thin-film transistors and capacitors.

The display element DE is an organic light emitting diode (OLED) as a light emitting element and thus may be called an organic EL element.

Although not described in detail, a terminal for connecting an IC chip and a flexible printed circuit is provided in the surrounding area SA.

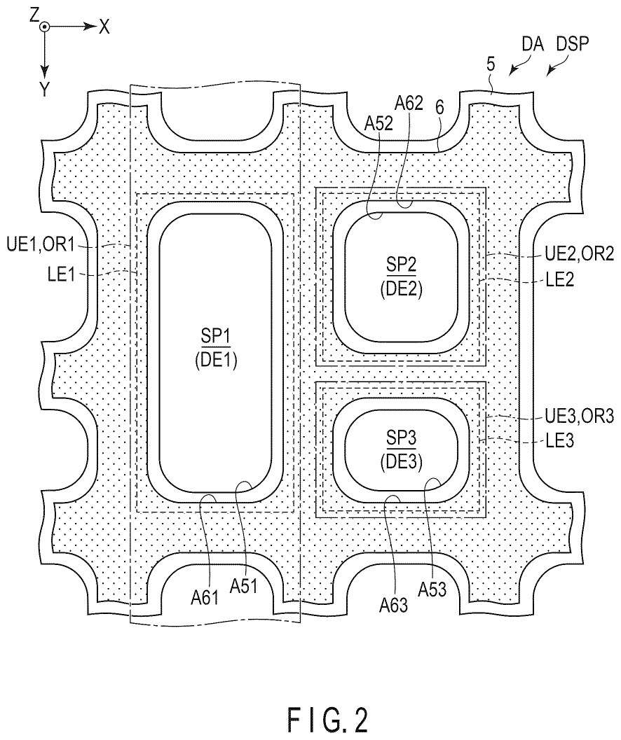

FIG. 2 is a schematic plan view showing an example of the layout of the subpixels SP1, SP2, and SP3. In the example of FIG. 2, the subpixels SP2 and SP3 are arranged in the second direction Y. The subpixels SP1 and SP2 are arranged in the first direction X. The subpixels SP1 and SP3 are arranged in the first direction X.

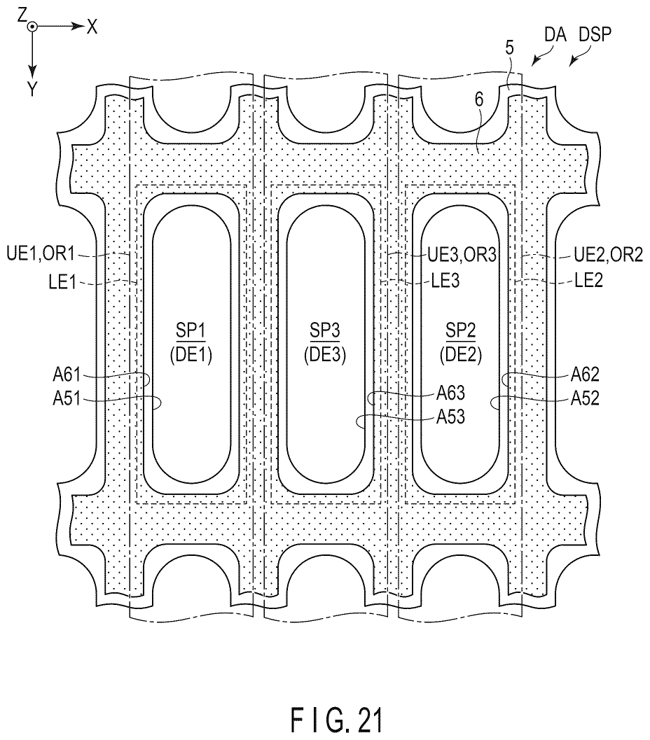

The layout of the subpixels SP1, SP2, and SP3 is not limited to the example of FIG. 2. As another example, the subpixels SP1, SP3, and SP2 in each pixel PX may be arranged in an order in the first direction X as shown in FIG. 21. This example will be described in detail later.

An inorganic insulating layer 5 and a partition 6 are provided in the display area DA. The inorganic insulating layer 5 includes apertures A51, A52, and A53 in the respective subpixels SP1, SP2 and SP3. The inorganic insulating layer 5, which has these apertures A51, A52, and A53 may be called a rib.

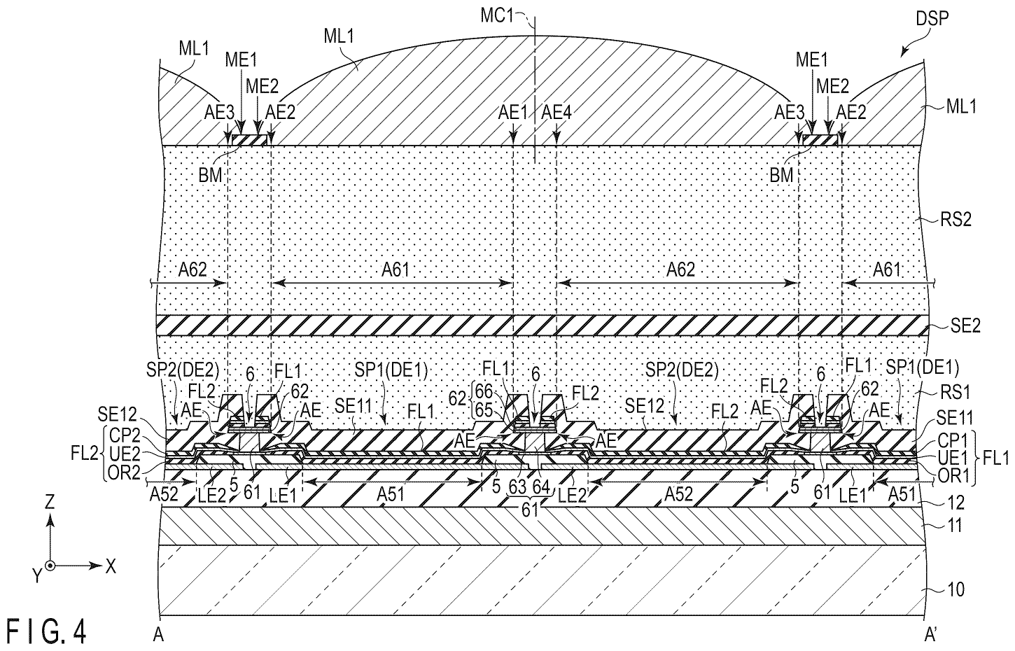

The partition 6 overlaps the inorganic insulating layer 5 in plan view. The partition 6 is formed into a grating shape surrounding the apertures A51, A52, and A53. The partition 6 includes apertures A61, A62, and A63 surrounded by an edge portion of an upper portion of the partition 6, which is to be described later with reference to FIG. 4. The aperture A61 (a first aperture) surrounds the aperture A51 in the subpixel SP1. The aperture A62 (a second aperture) surrounds the aperture A52 in the subpixel SP2. The aperture A63 (a third aperture) surrounds the aperture A53 in the subpixel SP3. In the example of FIG. 2, a corner portion of each of the apertures A51, A52, and A53 and the apertures A61, A62, and A63 has a round shape. The corner portion may have a right angle. Each of the apertures A51, A52, and A53 and the apertures A61, A62, and A63 may have other shapes such as a circular shape and an elliptic shape. The partition 6 is conductive and is electrically connected to a terminal having a common potential, of a plurality of terminals provided in the surrounding area SA shown in FIG. 1.

The subpixels SP1, SP2, and SP3 comprise display elements DE1, DE2, and DE3, respectively, as the display elements DE. The display elements DE1, DE2, and DE3 have light emitting layers formed of respective materials emitting light in different colors.

The display element DE1 (a first light emitting element) of the subpixel SP1 comprises a lower electrode LE1, an upper electrode UE1, and an organic layer OR1 that overlap each of the apertures A51 and A61. The display element DE1 comprising the lower electrode LE1, the organic layer OR1, and the upper electrode UE1 is surrounded by the aperture A61 in plan view. A peripheral portion of each of the lower electrode LE1, the organic layer OR1, and the upper electrode UE1 overlaps the inorganic insulating layer 5 in plan view. The organic layer OR1 includes a light emitting layer which emits light in, for example, a green wavelength range.

The display element DE2 (a second light emitting element) of the subpixel SP2 comprises a lower electrode LE2, an upper electrode UE2, and an organic layer OR2 that overlap each of the apertures A52 and A62. The display element DE2 comprising the lower electrode LE2, the organic layer OR2, and the upper electrode UE2 is surrounded by the aperture A62 in plan view. The display element DE2 is adjacent to the display element DE1 along the first direction X. A peripheral portion of each of the lower electrode LE2, the organic layer OR2, and the upper electrode UE2 overlaps the inorganic insulating layer 5 in plan view. The organic layer OR2 includes a light emitting layer which emits light in, for example, a blue wavelength range.

The display element DE3 (a third light emitting element) of the subpixel SP3 comprises a lower electrode LE3, an upper electrode UE3, and an organic layer OR3 that overlap each of the apertures A53 and A63. The display element DE3 comprising the lower electrode LE3, the organic layer OR3, and the upper electrode UE3 is surrounded by the aperture A63 in plan view. The display element DE3 is adjacent to the display element DE1 along the first direction X and is adjacent to the display element DE2 along the second direction Y. A peripheral portion of each of the lower electrode LE3, the organic layer OR3, and the upper electrode UE3 overlaps the inorganic insulating layer 5 in plan view. The organic layer OR3 includes a light emitting layer which emits light in, for example, a red wavelength range.

In the example of FIG. 2, the outer shapes of the lower electrodes LE1, LE2, and LE3 are indicated by dotted lines, and the outer shapes of the organic layers OR1, OR2, and OR3 and the upper electrodes UE1, UE2, and UE3 are indicated by one-dot chain line. The outlines of the respective lower electrode, organic layer, and upper electrode shown in the figure may not reflect the exact shapes.

For example, the lower electrodes LE1, LE2, and LE3 correspond to the anodes of the display elements. The upper electrodes UE1, UE2, and UE3 correspond to the cathodes of the display elements or a common electrode and are in contact with the partition 6.

In the example of FIG. 2, the area of the aperture A51, the area of the aperture A52, and the area of the aperture A53 are different from one another. The area of the aperture A51 is greater than the area of the aperture A52, and the area of the aperture A52 is greater than the area of the aperture A53. In other words, the area of the lower electrode LE1 exposed from the aperture A51 is greater than the area of the lower electrode LE2 exposed from the aperture A52, and the area of the lower electrode LE2 exposed from the aperture A52 is greater than the area of the lower electrode LE3 exposed from the aperture A53. The magnitude relationship among the apertures A51, A52, and A53 is not limited to the illustrated example.

Similarly, in the example of FIG. 2, the area of the aperture A61, the area of the aperture A62, and the area of the aperture A63 are different from one another. The area of the aperture A61 is greater than the area of the aperture A62. The area of the aperture A62 is greater than the area of the aperture A63. The magnitude relationship among the apertures A61, A62, and A63 is not limited to the illustrated example.

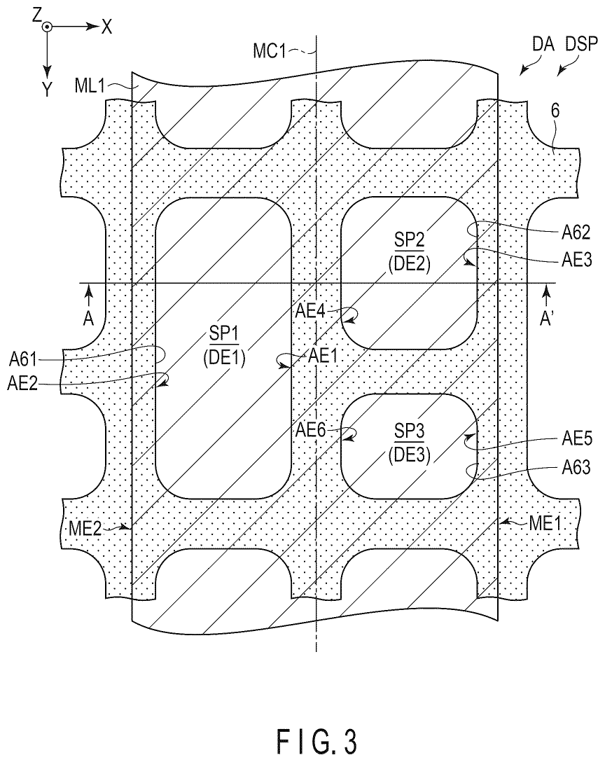

FIG. 3 is a plan view showing an example of the layout of the apertures A61, A62, and A63 and a lens ML1. The illustration of the lower electrode, organic layer, upper electrode, and the like that constitute the display element of each subpixel is omitted in FIG. 3.

In the aperture A61, the edge portion of the partition 6 includes aperture edges AE1 and AE2. The aperture edges AE1 and AE2 are parallel to the second direction Y. The aperture edges AE1 and AE2 face each other in the first direction X.

In the aperture A62, the edge portion of the partition 6 includes aperture edges AE3 and AE4. The aperture edges AE3 and AE4 are parallel to the second direction Y. The aperture edges AE3 and AE4 face each other in the first direction X.

In the aperture A63, the edge portion of the partition 6 includes aperture edges AE5 and AE6. The aperture edges AE5 and AE6 are parallel to the second direction Y. The aperture edges AE5 and AE6 face each other in the first direction X.

The display device DSP further comprises the lens ML1 (a first lens). The lens ML1 extend in the second direction Y, overlaps the apertures A61, A62, and A63 and the display elements DE1, DE2, and DE3. In the example of FIG. 3, the lens ML1 covers the apertures A61, A62, and A63.

The lens ML1 includes a lens edge ME1 (a first lens edge), a lens edge ME2 (a second lens edge), and a center line MC1. The lens edges ME and ME2 and the center line MC1 are parallel to the second direction Y. In the illustrated example, each of the lens edges ME1 and ME2 overlaps the partition 6 in plan view. Further, the center line MC1 overlaps the partition 6 in plan view and is located between the aperture edge AE1 and the aperture edge AE4 and between the aperture AE1 and the aperture edge AE6. The aperture A61 and the display element DE1 are located between the lens edge ME2 and the center line MC1 in the first direction X. The aperture A62, the display element DE2, the aperture A63, and the display element DE3 are located between the lens edge ME1 and the center line MC1 in the first direction X.

In this specification, the term “lens center line” signifies a line connecting a plurality of principal points of the lens. A principal point is a point at which the main surface of the lens and optical axis intersect each other. The main surface includes an intersection of light beam before being made incident and light beam after being made incident in a case of making light beam parallel to an optical axis incident on the lens and intersects the optical axis.

FIG. 4 is a cross-sectional view showing the configuration example of the display device DSP along line A-A′ in FIG. 3. The following describes the subpixels SP1 and SP2. The subpixel SP3 shown in FIG. 2 has the same configuration as those of the subpixels SP1 and SP2.

A circuit layer 11 is provided on the substrate 10. The circuit layer 11 includes various circuits such as the pixel circuit 1 shown in FIG. 1 and various lines such as the scanning line GL, the signal line SL, and the power line PL. The circuit layer 11 is covered with an insulating layer 12. The insulating layer 12 is an organic insulating layer which planarizes the uneven parts formed by the circuit layer 11.

The lower electrodes LE1 and LE2 are provided on the insulating layer 12 and are spaced apart from each other. The inorganic insulating layer 5 is provided on the insulating layer 12 and the lower electrodes LE1 and LE2. The aperture A51 of the inorganic insulating layer 5 overlaps the lower electrode LE1. The aperture A52 of the inorganic insulating layer 5 overlaps the lower electrode LE2. The peripheral portion of each of the lower electrodes LE1 and LE2 is covered with the inorganic insulating layer 5. In lower electrodes that are adjacent to each other among the lower electrodes LE1 and LE2, the insulating layer 12 is covered with the inorganic insulating layer 5. The lower electrodes LE1 and LE2 are connected to the pixel circuit 1 of each of the subpixels SP1 and SP2 through a contact hole provided in the insulating layer 12. The illustration of the contact hole of the insulating layer 12 is omitted in FIG. 4.

The partition 6 includes a conductive lower portion 61 provided on the inorganic insulating layer 5 and an upper portion 62 provided on the lower portion 61. The lower portion 61 surrounds each of the display elements DE1 and DE2 in plan view. The upper portion 62 includes an edge portion AE surrounding each of the apertures A61 and A62 in plan view. The edge portion AE projects relative to the side surfaces of the lower portion 61. This shape of the partition 6 is called an overhang shape.

In the illustrated example, the lower portion 61 includes a first conductive layer 63 provided on the inorganic insulating layer 5 and a second conductive layer 64 provided on the first conductive layer 63. For example, the first conductive layer 63 is thinner than the second conductive layer 64. Further, in the illustrated example, the both end portions of the first conductive layer 63 project relative to the respective side surfaces of the second conductive layer 64.

The upper portion 62 includes a thin film 65 provided on the second conductive layer 64 and a thin film 66 provided on the thin film 65. The both end portions of the thin film 65 and the both end portions of the thin film 66 project relative to the respective side surfaces of the second conductive layer 64. In the illustrated example, the edge portion AE of the thin film 65 surrounds the apertures A61 and A62. The edge portion AE corresponds to, for example, the end portions of the thin film 65.

The organic layer OR1 is in contact with the lower electrode LE1 through the aperture A51 and covers the lower electrode LE1 exposed from the aperture A51. The peripheral portion of the organic layer OR1 is located on the inorganic insulating layer 5. The upper electrode UE1 covers the organic layer OR1 and is in contact with the lower portion 61.

The organic layer OR2 is in contact with the lower electrode LE2 through the aperture A52 and covers the lower electrode LE2 exposed from the aperture A52. The peripheral portion of the organic layer OR2 is located on the inorganic insulating layer 5. The upper electrode UE2 covers the organic layer OR2 and is in contact with the lower portion 61.

In the example of FIG. 4, the subpixel SP1 includes a cap layer CP1 and a first sealing layer SE11. The subpixel SP2 includes a cap layer CP2 and a first sealing layer SE12. The cap layers CP1 and CP2 function as optical adjustment layers which improve the extraction efficiency of light emitted from the respective organic layers OR1 and OR2. The cap layers CP1 and CP2 may be omitted. The cap layer CP1 is provided on the upper electrode UE1. The cap layer CP2 is provided on the upper electrode UE2.

The first sealing layer SE11 is provided on the cap layer CP1, is in contact with the partition 6, and continuously covers each member of the subpixel SP1. The first sealing layer SE12 is provided on the cap layer CP2, is in contact with the partition 6, and continuously covers each member of the subpixel SP2.

In the example of FIG. 4, portions of the organic layer OR1, the upper electrode UE1, and the cap layer CP1 are located on the partition 6 around the subpixel SP1. These portions are spaced apart from portions located in the aperture A51 (the portions constituting the display element DE1) of the organic layer OR1, the upper electrode UE1, and the cap layer CP1.

Similarly, portions of the organic layer OR2, the upper electrode UE2, and the cap layer CP2 are located on the partition 6 around the subpixel SP2. These portions are spaced apart from the portions located in the aperture A52 (the portions constituting the display element DE2) of the organic layer OR2, the upper electrode UE2, and the cap layer CP2.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2.

The end portions of each of the first sealing layers SE11 and SE12 and the end portions of each of the stacked films FL1 and FL2 are located on the partition 6. In the example of FIG. 4, the stacked film FL1 on the partition 6 and the first sealing layer SE11 between the subpixels SP1 and SP2 are spaced apart from the stacked film FL2 located on this partition 6 and the first sealing layer SE12.

The partition 6 and the first sealing layers SE11 and SE12 are covered with an organic insulating layer RS1 (a first organic insulating layer). The organic insulating layer RS1 is covered with a second sealing layer SE2. The second sealing layer SE2 is covered with an organic insulating layer RS2 (a second organic insulating layer). In the illustrated example, the organic insulating layer RS2 is thicker than the organic insulating layer RS1.

The lens ML1 is provided on the organic insulating layer RS2. The lens ML1 has a convex shape projecting toward the side opposite to the substrate 10 in the third direction Z. In the illustrated example, the section of the lens ML1 has a semielliptical shape. The lens ML1 overlaps the lower electrodes LE1 and LE2, the stacked films FL1 and FL2, and the first sealing layers SE11 and SE12 in the third direction Z. As an example, the lens ML1 is covered with an air layer. As another example, the lens ML1 is covered with a material that has the refractive index smaller than that of the lens ML1.

The center line MC1 is provided on the thickest portion of the lens ML1 and is located directly above the partition 6.

A focus of the lens ML1 is preferably in alignment with the position of the light emitting layer included in the organic layer OR1. The position of the focus of the lens ML1 can be in alignment with the position of the light emitting layer, for example, by varying the thicknesses of the organic insulating layers RS1 and RS2.

A cover member such as a polarizer and a cover glass may further be provided above the lens ML1.

The display device DSP further comprises a light-shielding layer BM provided on the organic insulating layer RS2. The light-shielding layer BM covers space among the plurality of lenses ML1 that are adjacent to one another in the first direction X. In the illustrated example, the light-shielding layer BM overlaps the lens edges ME1 and ME2. Further, the both end portions of the light-shielding layer BM are covered with the plurality of lenses ML1.

Each of the inorganic insulating layer 5, the first sealing layers SE11 and SE12, and the second sealing layer SE2 is formed of, for example, an inorganic insulating material such as silicon nitride (SiNx), silicon oxide (SiOx), silicon oxynitride (SiON), or aluminum oxide (Al₂O₃). Each of the organic insulating layers RS1 and RS2 is formed of, for example, a resinous material (an organic insulating material) such as epoxy resin or acrylic resin.

The lower portion 61 of the partition 6 is formed of a conductive material and is electrically connected to the upper electrodes UE1 and UE2. The first conductive layer 63 is formed of, for example, titanium-based material such as titanium and titanium compound. The second conductive layer 64 is formed of a material that is different from each of the first conductive layer 63 and the upper portion 62. For example, the second conductive layer 64 is formed of aluminum-based material such as aluminum and aluminum compound.

The upper portion 62 of the partition 6 is formed of, for example, a conductive material. However, the upper portion 62 may be formed of an insulating material. The thin film 65 is, formed of, for example, titanium-based material such as titanium and titanium compound. The thin film 66 is formed of, for example, oxide conductive material such as indium tin oxide (ITO).

Each of the lower electrodes LE1 and LE2 is a multilayer body including a transparent layer formed of an oxide conductive material such as indium tin oxide (ITO) and a reflective layer formed of a metal material such as silver. For example, each of the lower electrodes LE1 and LE2 is a multilayer body including the reflective layer between a pair of transparent layers. The transparent layer of the lower layer functions as a close-contact layer in close contact with the insulating layer 12.

As an example, the organic layer OR1 includes a light emitting layer formed of a material emitting light in a green color, and the organic layer OR2 includes a light emitting layer formed of a material emitting light in a blue color. As another example, the organic layer OR1 includes a light emitting layer formed of a material emitting light in a blue color, and the organic layer OR2 includes a light emitting layer formed of a material emitting light in a green color. Each of the organic layers OR1 and OR2 includes a plurality of functional layers such as a hole injection layer, a hole transport layer, an electron blocking layer, a hole blocking layer, an electron transport layer, and an electron injection layer.

The upper electrodes UE1 and UE2 are formed of, for example, a metal material such as an alloy of magnesium and silver (MgAg). Each of the cap layers CP1 and CP2 is a multilayer body consisting of a plurality of thin films. All of the thin films are transparent and have refractive indexes different from one another.

The lens ML1 is formed of, for example, a transparent resinous material such as epoxy resin, acrylic resin, and polyimide resin.

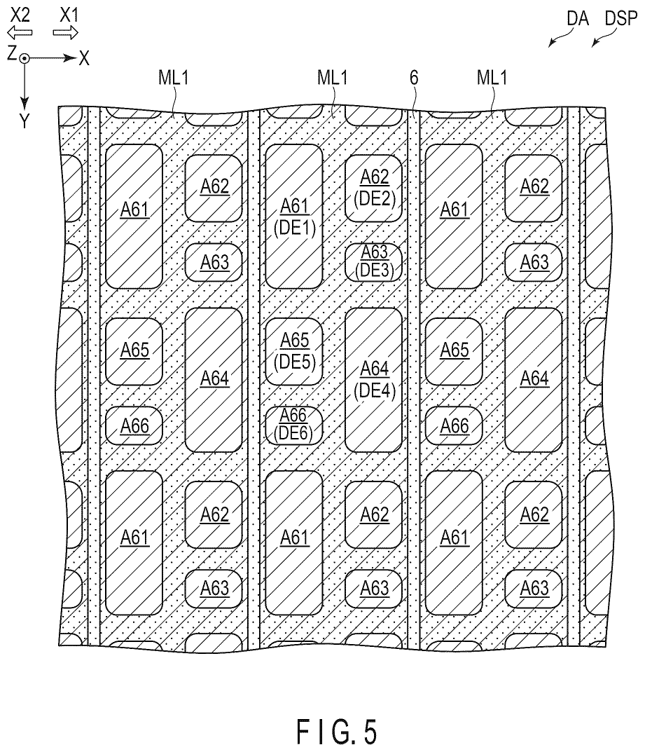

FIG. 5 is a schematic plan view showing an example of the layout of the apertures A61 to A66. The display device DSP further comprises display elements DE4, DE5, and DE6. The display element DE4 (a fourth light emitting element) is adjacent to the display elements DE5 and DE6 in the first direction X and is adjacent to the display element DE3 in the second direction Y. The display element DE5 (a fifth light emitting element) is adjacent to the display element DE4 in the first direction X and is adjacent to the display elements DE1 and DE6 in the second direction Y. The display element DE6 (a sixth light emitting element) is adjacent to the display element DE4 in the first direction X and is adjacent to the display element DE5 in the second direction Y.

The display element DE4 has the same configuration as that of the display element DE1. That is, the display element DE4 includes a light emitting layer formed of a material exhibiting the same color as that of the display element DE1. The display element DE5 has the same configuration as that of the display element DE2. That is, the display element DE5 includes a light emitting layer formed of a material exhibiting the same color as that of the display element DE2. The display element DE6 has the same configuration as that of the display element DE3. That is, the display element DE6 includes a light emitting layer formed of a material exhibiting the same color as that of the display element DE3.

The color of light emitted by the display elements DE1 and DE4 (the first color), the color of light emitted by the display elements DE2 and DE5 (the second color), and the color of light emitted by the display elements DE3 and DE6 (the third color) are different from one another.

The partition 6 further includes apertures A64, A65, and A66 surrounded by the edge portion AE of the partition 6 (refer to FIG. 4). The aperture A64 (a fourth aperture) overlaps the display element DE4. The aperture A65 (a fifth aperture) overlaps the display element DE5. The aperture A66 (a sixth aperture) overlaps the display element DE6. A row in which the apertures A61, A65, and A66 are arranged in the second direction Y and a row in which the apertures A62, A63, and A64 are arranged in the second direction Y are formed in the display area DA. These rows are alternately arranged in the first direction X. The lens ML1 overlaps the apertures A64, A65, and A66 and the display elements DE4, DE5, and DE6.

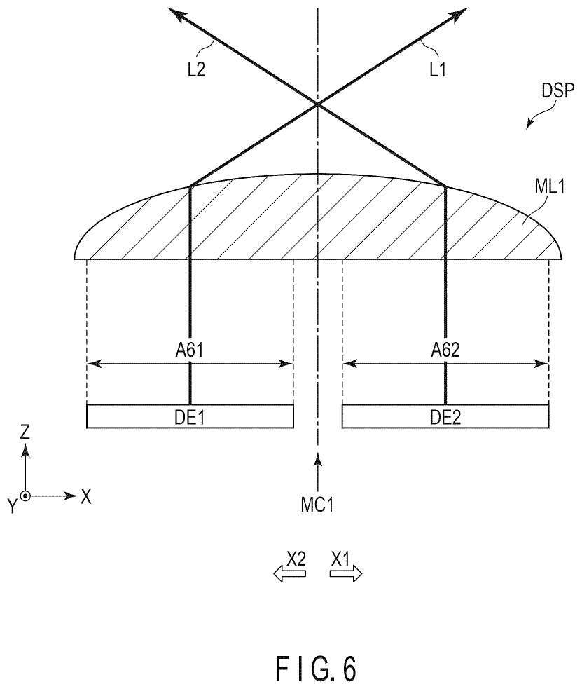

Next, effects of the present embodiment will be described with reference to FIG. 6. FIG. 6 is a diagram for explaining effects of the present embodiment. A direction toward the center line MC1 from the display element DE1 along the first direction X is hereinafter referred to as a direction X1. A direction toward the center line MC1 from the display element DE2 along the first direction X is hereinafter referred to as a direction X2.

Light beam L1 emitted along the third direction Z from the display element DE1 that is located on the direction X2 side with respect to the center line MC1 is refracted at the interface between the lens ML1 and air and travels along a direction tilted from the third direction Z to the direction X1 side. In contrast, light beam L2 emitted along the third direction Z from the display element DE2 that is located on the direction X1 side with respect to the center line MC1 is refracted at the interface between the lens ML1 and air and travels along a direction tilted from the third direction Z to the direction X2 side.

That is, a user in a traveling direction side of the light beam L1 can visually recognize light emitted from the display element DE1 but hardly visually recognizes light emitted from the display element DE2. In contrast, a user in a traveling direction side of the light beam L2 can visually recognize light emitted from the display element DE2 but hardly visually recognizes light emitted from the display element DE1.

In the example shown in FIG. 5, a user in the direction X1 side with respect to the display device DSP can visually recognize light emitted from the display elements DE1, DE5, and DE6, but hardly visually recognizes light emitted from the display elements DE2, DE3, and DE4. In contrast, a user in the direction X2 side with respect to the display device DSP can visually recognize light emitted from the display elements DE2, DE3, and DE4, but hardly visually recognizes light emitted from the display elements DE1, DE5, and DE6. Therefore, the viewing angle of the display device DSP can be limited.

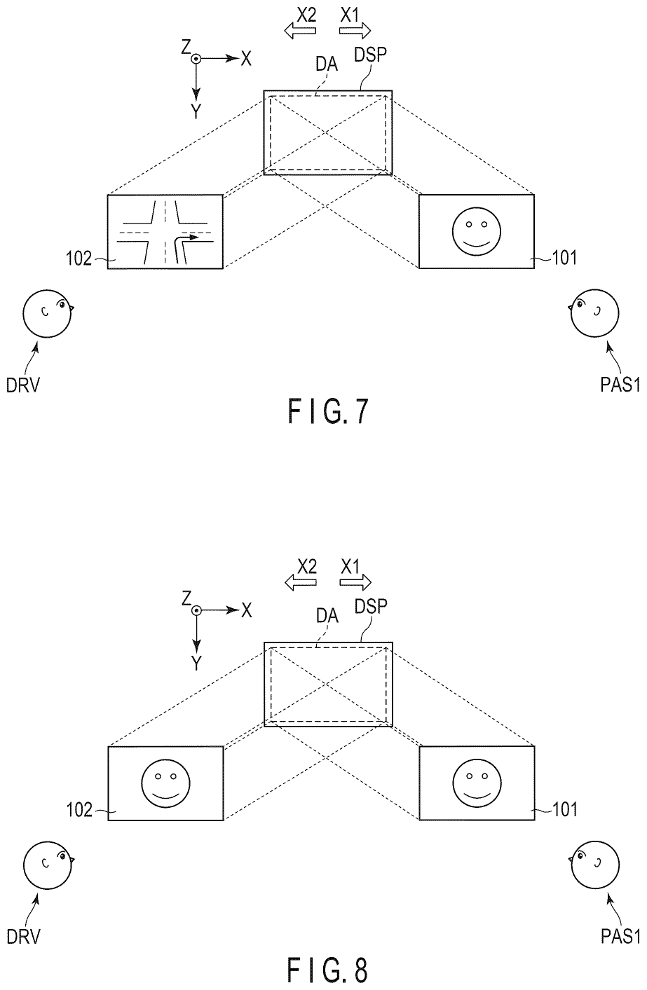

Next, a case where the display device DSP of the present embodiment will be mounted on a vehicle such as an automobile will be described. FIG. 7 to FIG. 9 are diagrams showing the display device DSP of the present embodiment that is mounted on a vehicle-mounted device. As an example, a case in which the display device DSP is located between a driver seat and a front passenger seat will be described.

For example, as shown in FIG. 7, it is required that different images are visually recognizable from respective driver seat side and front passenger seat side. When the display elements DE1 to DE6 in the display area DA are arranged in the layout shown in the example of FIG. 5, a passenger PAS1 sitting in the front passenger seat in the direction X1 side with respect to the display device DSP can visually recognize light emitted from the display elements DE1, DE5, and DE6. In contrast, a driver DRV sitting in the direction X2 side with respect to the display device DSP can visually recognize light emitted from the display elements DE2, DE3, and DE4. That is, the display elements DE1, DE5, and DE6 are supplied with image signals for displaying an image for the passenger PAS1 in the front passenger seat, and the display elements DE2, DE3, and DE4 are supplied with images signal for displaying an image for the driver DRV. This configuration allows the passenger PAS1 and the driver DRV to visually recognize display screens 101 and 102, respectively. The display screens 101 and 102 display images different from each other.

As shown in FIG. 8, for example, in a case where the engine is in the off state and it is required that the same image is visually recognizable from the driver seat side and the front passenger seat side, the display element DE1 is supplied with the same image signal as that of the display element DE4, the display element DE5 is supplied with the same image signal as that of the display element DE2, and the display element DE6 is supplied with the same image signal as that of the display element DE3. This configuration allows the passenger PAS1 in the front passenger seat and the driver DRV can visually recognize the display screens 101 and 102 on which the same image is displayed.

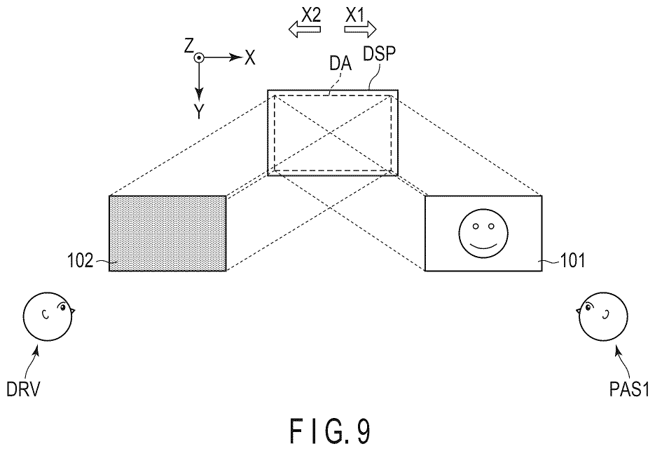

As shown in FIG. 9, for example, at the time of driving, when it is required that an image is hardly visually recognizable from the driver seat side and, in contrast, this image is visually recognizable from the front passenger seat side, the display elements DE1, DE5, and DE6 are supplied with the image signals and the display elements DE2, DE3, and DE4 are not supplied with the image signals. Therefore, the display elements DE1, DE5, and DE6 are illuminated according to the image signals. In contrast, the display elements DE2, DE3, and DE4 are not illuminated. This configuration allows the passenger PAS1 in the front passenger seat to visually recognize the display screen 101 on which an image is displayed, and allows the driver DRV to visually recognize the display screen 102, which is dark and an image is hardly displayed on.

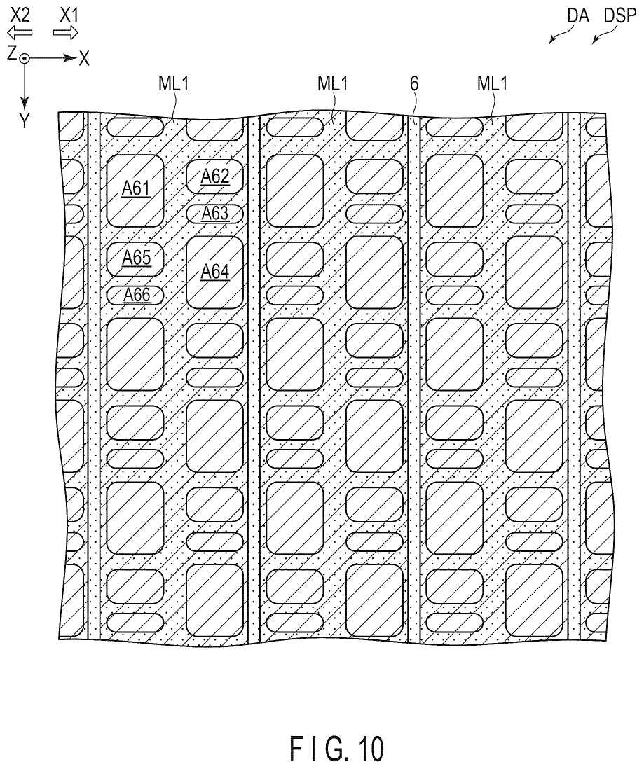

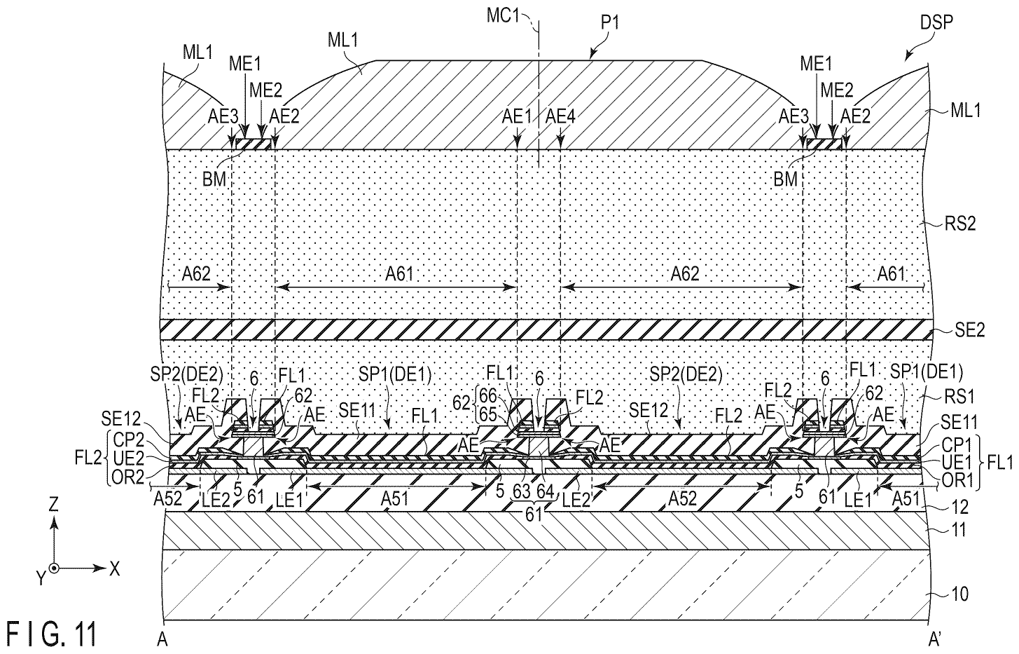

FIG. 10 is a schematic plan view showing another example of the layout of the apertures A61 to A66 shown in FIG. 5. The length along the second direction Y of each of the apertures A61 to A66 shown in FIG. 10 is approximately half the length along the second direction Y of each of the apertures A61 to A66 shown in FIG. 5. Thus, the number of the pixels of the display device DSP shown in FIG. 10 is approximately twice the number of the pixels of the display device DSP shown in FIG. 5. This configuration can increase the resolution of the display screen 101 visually recognizable by the passenger PAS1 in the front passenger seat and the resolution of the display screen 102 visually recognizable by the driver DRV. Here, the resolution signifies the number of the pixels contributing to displaying per unit area.

FIG. 11 is a cross-sectional view showing another configuration example of the display device DSP along line A-A′ in FIG. 3. The display device DSP shown in FIG. 11 is different from the display device DSP shown in FIG. 4 in the cross-sectional shape of the lens ML1.

The lens ML1 has a flat surface P1 on its apex portion. In the example of FIG. 11, the surface P1 is parallel to the first direction X and the second direction Y. The surface P1 may be inclined to a surface defined by the first direction X and the second direction Y.

The display device DSP shown in FIG. 11 can exhibit the same effects as those achieved by the display device DSP shown in FIG. 4.

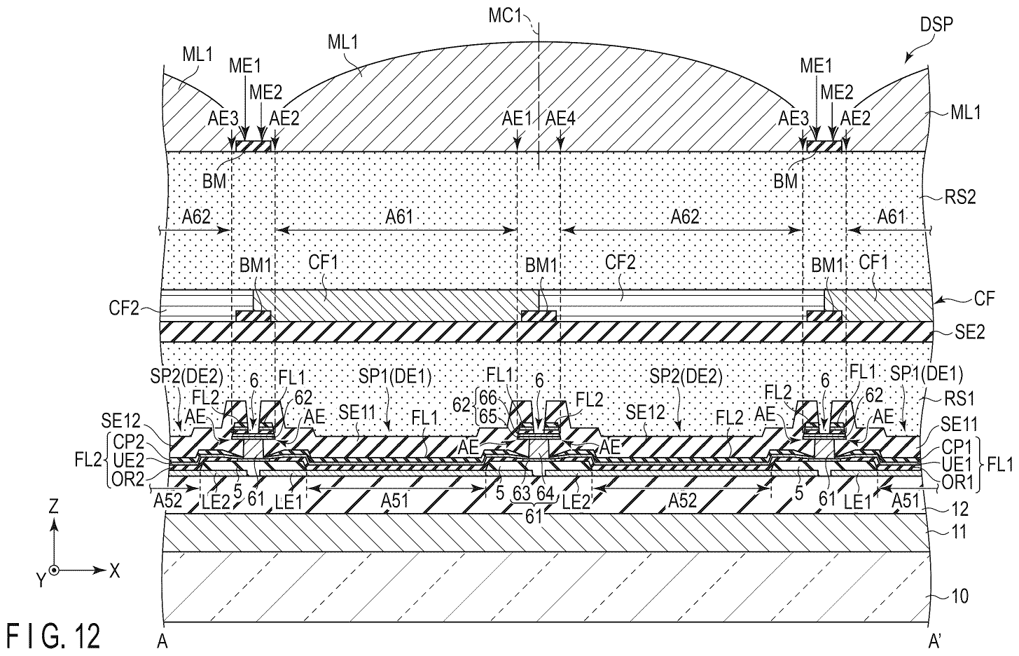

FIG. 12 is a cross-sectional view showing still another configuration example of the display device DSP along line A-A′ in FIG. 3. The display device DSP further comprises a color filter layer CF. The color filter layer CF comprises color filters CF1 and CF2 and a light-shielding layer BM1. The color filter layer CF is provided between the second sealing layer SE2 and the organic insulating layer RS2 in the third direction Z.

The color filter CF1 is provided directly above the display element DE1. The color filter CF1 has the color of the same type as the color exhibited by the display element DE1. As an example, the color filter CF1 is formed of a green-colored resin material. The color filter CF2 is provided directly above the display element DE2. The color filter CF2 has the color of the same type as the color exhibited by the display element DE2. As an example, the color filter CF2 is formed of a blue-colored resin material.

The light-shielding layer BM1 overlaps a peripheral portion of each of the color filters CF1 and CF2. In the illustrated example, the light-shielding layer BM1 overlaps the lens edges ME1 and ME2 in the third direction Z.

Though not illustrated, the color filter layer CF comprises a color filter provided directly above the display element DE3 shown in FIG. 2. The color filter has the color of the same type as the color exhibited by the display element DE3. As an example, the color filter is formed of a red-colored resin material.

In the display device DSP shown in FIG. 12, for example, green light emitted from the display element DE1 passes through the color filter CF1. In contrast, blue light emitted from the display element DE2 is absorbed by the color filter CF1. Thus, color mixture in light can be suppressed. This results in suppressing the degradation in display quality.

The display device DSP shown in FIG. 12 can exhibit the same effects as those achieved by the display device DSP shown in FIG. 4.

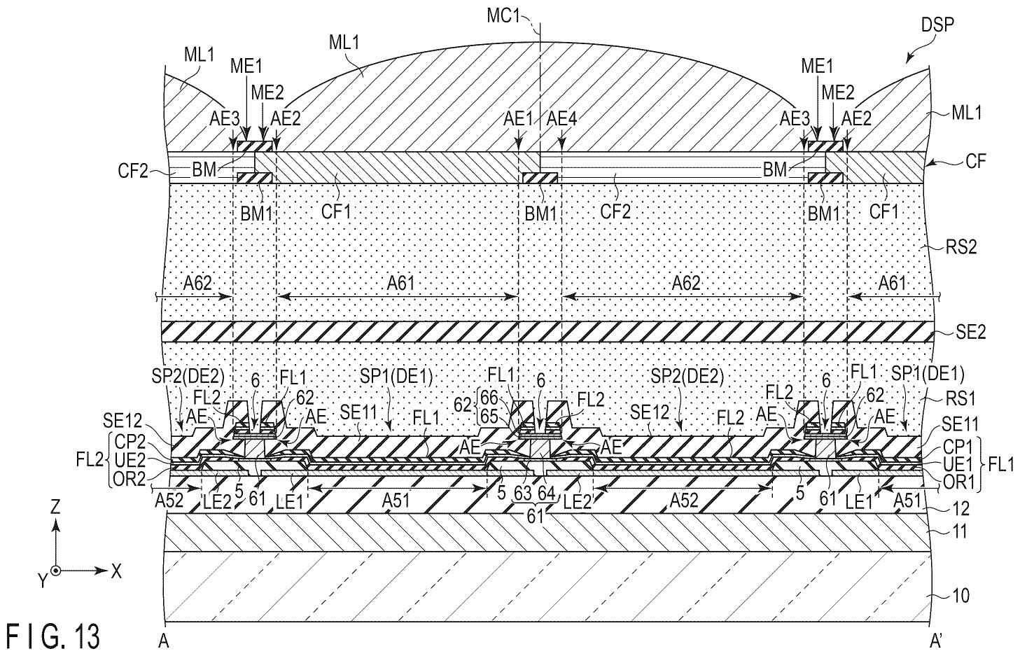

FIG. 13 is a cross-sectional view showing still another configuration example of the display device DSP along line A-A′ in FIG. 3. In the illustrated example, the color filter layer CF is provided between the organic insulating layer RS2 and the plurality of lenses ML1 in the third direction Z. The position of the color filter layer CF is not limited to the examples shown in FIG. 12 and FIG. 13.

The display device DSP shown in FIG. 13 can exhibit the same effects as those achieved by the display device DSP shown in FIG. 4.

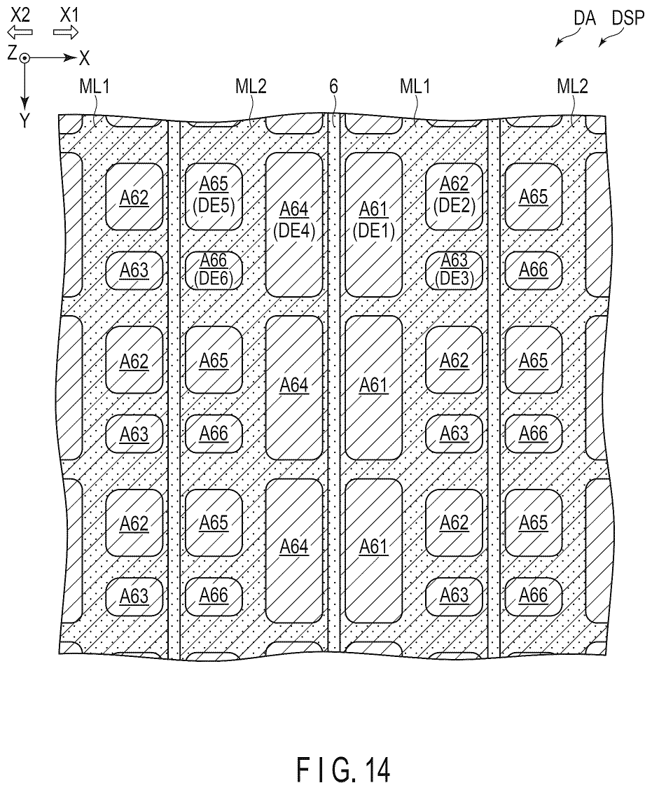

FIG. 14 is a schematic plan view showing another example of the layout of the apertures A61 to A66. The display element DE4 is adjacent to the display elements DE1, DE5, and DE6 in the first direction X. The display element DE5 is adjacent to the display element DE4 in the first direction X and is adjacent to the display element DE6 in the second direction Y. The display element DE6 is adjacent to the display element DE4 in the first direction X and is adjacent to the display element DE5 in the second direction Y. As described above, the apertures A61 to A66 overlap the display elements DE1 to DE6, respectively.

A row in which the plurality of apertures A61 are arranged in the second direction Y, a row in which the apertures A62 and A63 are alternately arranged in the second direction Y, a row in which the apertures A65 and A66 are alternately arranged in the second direction Y, and a row in which the plurality of apertures A64 are arranged in the second direction Y are formed in the display area DA. These rows are arranged in the first direction X.

The display device DSP comprises the lens ML1 overlapping the apertures A61, A62, and A63 and the display elements DE1, DE2, and DE3 and a lens ML2 overlapping the apertures A64, A65, and A66 and the display elements DE4, DE5, and DE6. The lens ML2 has the same configuration as that of the lens ML1. The lenses ML1 and ML2 are alternately arranged in the first direction X.

In the example shown in FIG. 14, a user in the direction X1 side with respect to the display device DSP can visually recognize light emitted from the display elements DE1, DE5, and DE6. In contrast, a user in the direction X2 side with respect to the display device DSP can visually recognize light emitted from the display elements DE2, DE3, and DE4. That is, by suppling the display elements DE1, DE5, and DE6 and the display elements DE2, DE3, and DE4 with different image signals, a user in the direction X1 side and a user in the direction X2 side can visually recognize respective images different from each other.

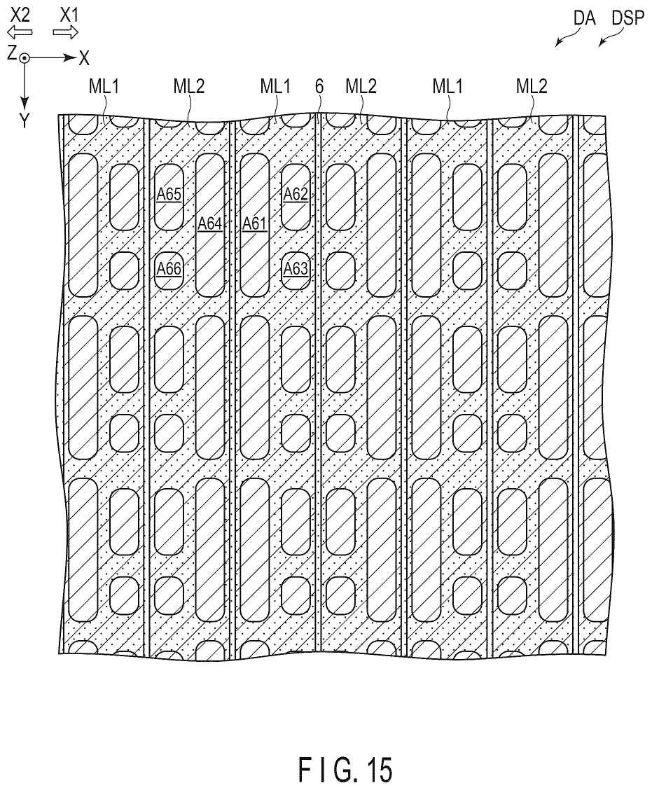

FIG. 15 is a schematic plan view showing another example of the layout of the apertures A61 to A66 shown in FIG. 14. The length along the first direction X of each of the apertures A61 to A66 in FIG. 15 is approximately half the length along the first direction X of each of the apertures A61 to A66 in FIG. 14. Thus, the number of the pixels of the display device DSP shown in FIG. 15 is approximately twice the number of the pixels of the display device DSP shown in FIG. 14. This configuration can increase the resolution of the display screen 101 visually recognizable by the passenger PAS1 in the front passenger seat and the resolution of the display screen 102 visually recognizable by the driver DRV.

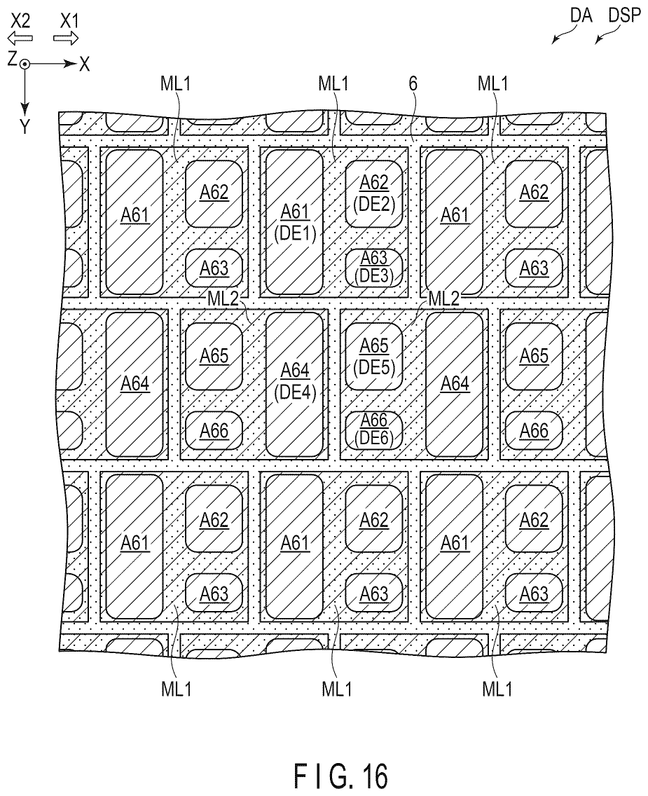

FIG. 16 is a schematic plan view showing still another example of the layout of the apertures A61 to A66. The display element DE4 is adjacent to the display elements DE5 and DE6 in the first direction X and is adjacent to the display element DE1 in the second direction Y. The display element DE5 is adjacent to the display element DE4 in the first direction X and is adjacent to the display elements DE3 and DE6 in the second direction Y. The display element DE6 is adjacent to the display element DE4 in the first direction X and is adjacent to the display element DE5 in the second direction Y. As described above, the apertures A61 to A66 overlap the display elements DE1 to DE6, respectively.

A row in which the apertures A61 and A64 are alternately arranged in the second direction Y and a row in which the apertures A62, A63, A65, and A66 are arranged in the second direction Y are formed in the display area DA. These rows are alternately arranged in the first direction X.

The display device DSP comprises the lens ML1 overlapping the apertures A61, A62, and A63 and the display elements DE1, DE2, and DE3 and the lens ML2 overlapping the apertures A64, A65, and A66 and the display elements DE4, DE5, and DE6. The lens ML2 is provided in the first direction X between the lenses ML1 adjacent to each other in the first direction X. A row in which the plurality of lenses ML1 are arranged in the first direction X and a row in which the plurality of lenses ML2 are arranged in the first direction X are formed in the display area DA. These rows are alternately arranged in the second direction Y.

Among the lenses ML2 adjacent to each other in the first direction X, the lens ML2 that is located on the direction X2 side with respect to the lens ML1 is a second lens, and the lens ML2 that is located on the direction X1 side with respect to the lens ML1 is a third lens.

In the example shown in FIG. 16, a user in the direction X1 side with respect to the display device DSP can visually recognize light emitted from the display elements DE1, DE5, and DE6. In contrast, a user in the direction X2 side with respect to the display device DSP can visually recognize light emitted from the display elements DE2, DE3, and DE4. That is, by suppling the display elements DE1, DE5, and DE6 and the display elements DE2, DE3, and DE4 with different image signals, a user in the direction X1 side and a user in the direction X2 side can visually recognize respective images different from each other.

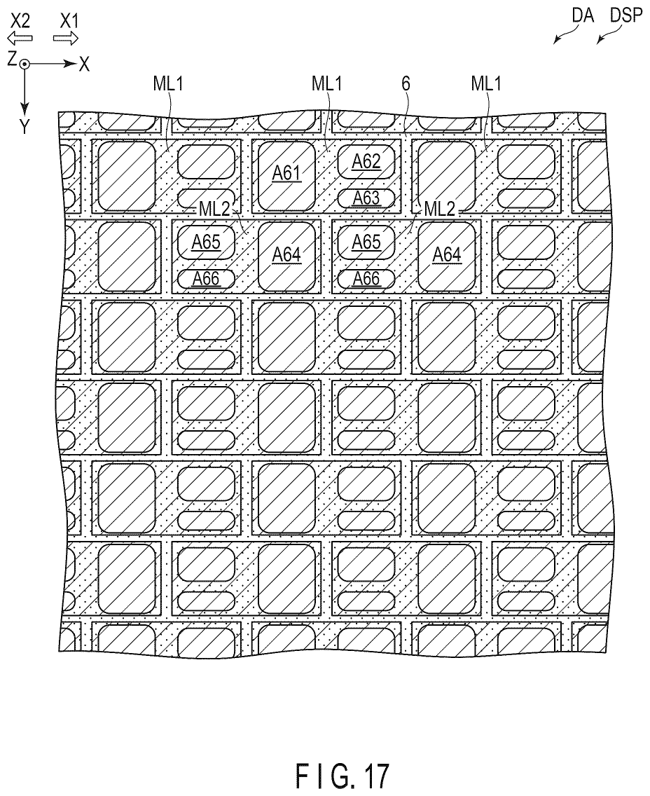

FIG. 17 is a schematic plan view showing another example of the layout of the apertures A61 to A66 shown in FIG. 16. The length along the second direction Y of each of the apertures A61 to A66 in FIG. 17 is approximately half the length along the second direction Y of each of the apertures A61 to A66 in FIG. 16. Thus, the number of the pixels of the display device DSP shown in FIG. 17 is approximately twice the number of the pixels of the display device DSP shown in FIG. 16. This configuration can increase the resolution of the display screen 101 visually recognizable by the passenger PAS1 in the front passenger seat and the resolution of the display screen 102 visually recognizable by the driver DRV.

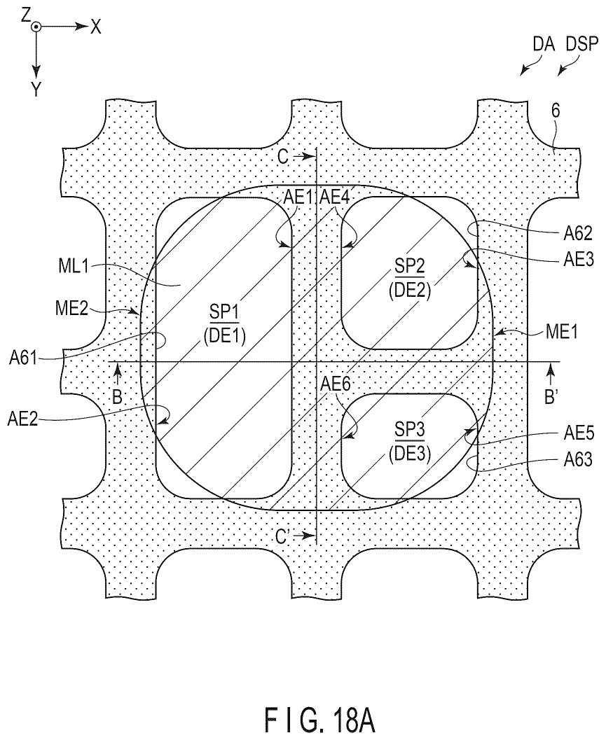

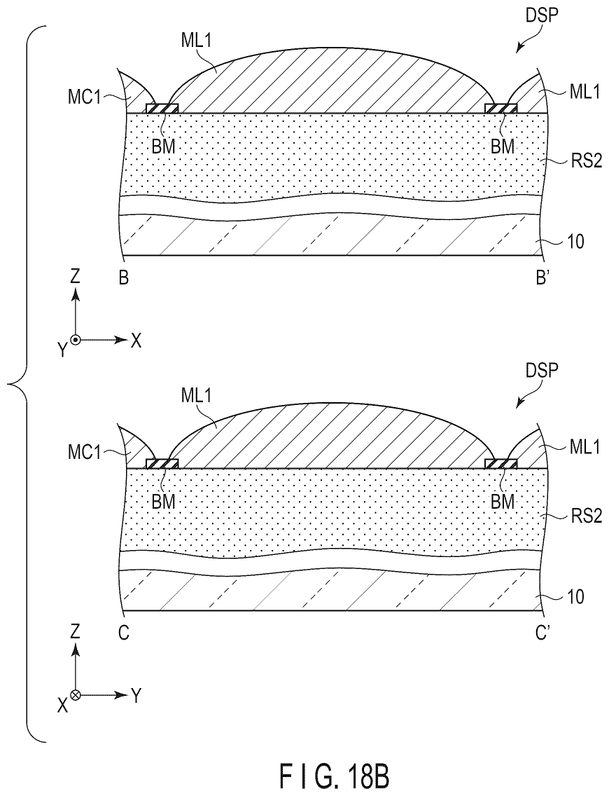

FIG. 18A is a plan view showing another example of the layout of the apertures A61, A62, and A63 and the lens ML1. In the example shown in FIG. 18A, the lens ML1 has a shape in which the corner portion of the rectangular shape is rounded in plan view. The lens ML1 may have an elliptic shape or a circular shape in plan view. Of the apertures A61, A62, and A63, portions that do not overlap the lens ML1 overlap a light-shielding layer BM that is not shown (the light-shielding layer BM shown in FIG. 4).

FIG. 18B is a cross-sectional view showing a configuration example of the display device DSP along line B-B′ and line C-C′ in FIG. 18A. The upper half of FIG. 18B is a cross-sectional view showing a configuration example of the display device DSP along line B-B′ in FIG. 18A. The cross-sectional shape along the first direction X of the lens ML1 is a convex shape projecting toward the side opposite to the substrate 10. This configuration limits the viewing angle of the first direction X as describe above.

The lower half of FIG. 18B is a cross-sectional view showing a configuration example of the display device DSP along line C-C′ in FIG. 18A. The cross-sectional shape along the second direction Y of the lens ML1 is a convex shape projecting toward the side opposite to the substrate 10. Similarly to the first direction X, the viewing angle of the second direction Y is limited. By limiting the viewing angle of the second direction Y, for example, in a case where the display device DSP is mounted on an automobile, a reflection of a display image on a windshield of the automobile can be suppressed.

In FIG. 18B, the illustration of the portions located between the organic insulating layer RS2 and the substrate 10 is omitted. Each of the above described configurations can be adopted as the configuration located between the organic insulating layer RS2 and the substrate 10.

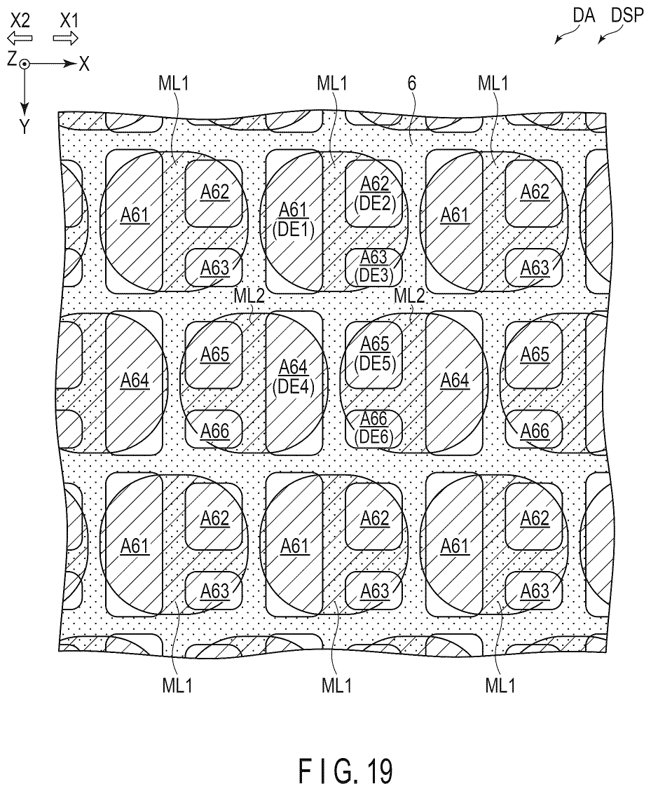

FIG. 19 is a schematic plan view showing still another example of the layout of the apertures A61 to A66. The layout of the display elements DE1 to DE6, the apertures A61 to A66, and the lenses ML1 and ML2 shown in FIG. 19 is the same as the layout of the display elements DE1 to DE6, the apertures A61 to A66, and the lenses ML1 and ML2 shown in FIG. 16. In a case of this layout, the viewing angle of the first direction X and the second direction Y can be limited.

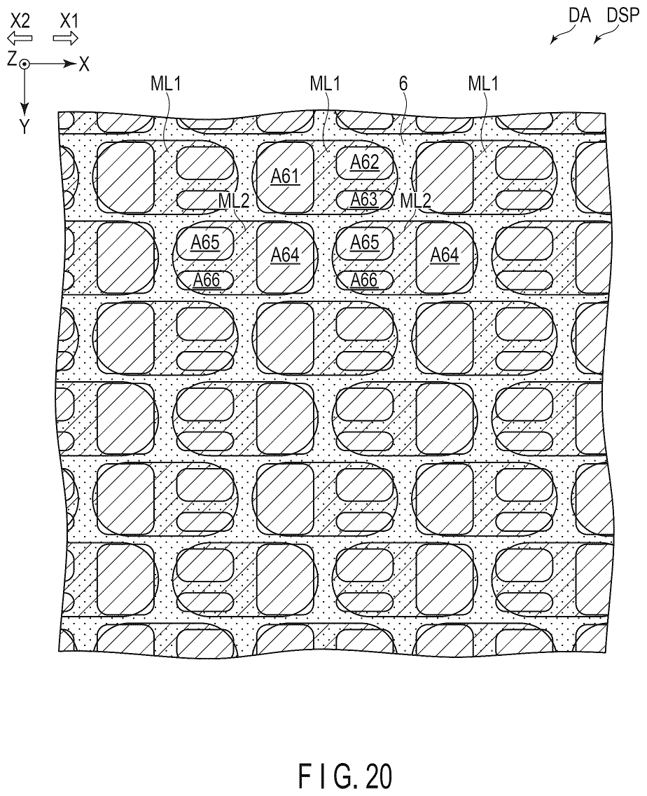

FIG. 20 is a schematic plan view showing another example of the layout of the apertures A61 to A66 shown in FIG. 19. The length along the second direction Y of each of the apertures A61 to A66 shown in FIG. 20 is approximately half the length along the second direction Y of each of the apertures A61 to A66 shown in FIG. 19. Thus, the number of the pixels of the display device DSP shown in FIG. 20 is approximately twice the number of the pixels of the display device DSP shown in FIG. 19. This configuration can increase the resolution of the display screen 101 visually recognizable by the passenger PAS1 in the front passenger seat and the resolution of the display screen 102 visually recognizable by the driver DRV.

FIG. 21 is a schematic plan view showing another example of the layout of the subpixels SP1, SP2, and SP3. In the example of FIG. 21, the subpixel SP3 is located between the subpixel SP1 and the subpixel SP2 in the first direction X.

In the example of FIG. 21, the areas of the apertures A51, A52, and A53 are equivalent to one another. The areas of the apertures A51, A52, and A53 may be different from one another.

Similarly, the areas of the apertures A61, A62, and A63 are equivalent to one another. The areas of the apertures A61, A62, and A63 may be different from one another.

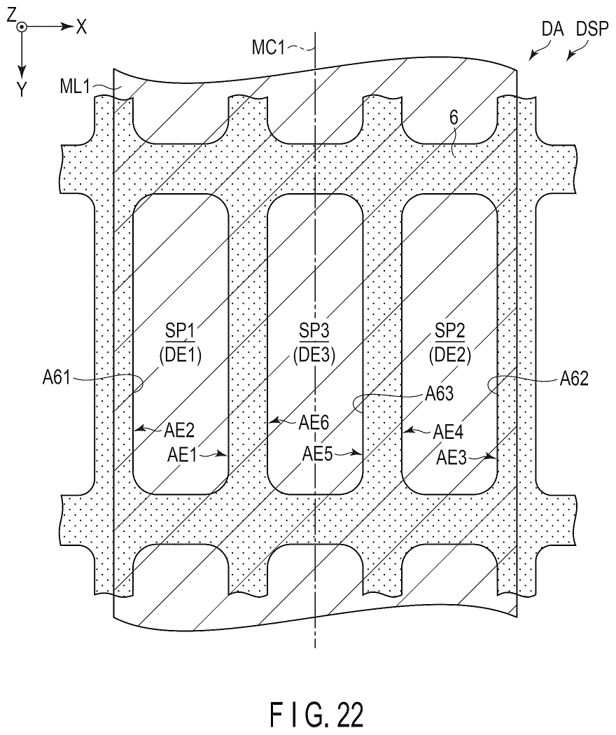

FIG. 22 is a plan view showing another example of the layout of the apertures A61, A62, and A63 and the lens ML1. In FIG. 22, the illustration of the lower electrode, organic layer, upper electrode, and the like that constitute the display element of each subpixel is omitted.

The lens ML1 overlaps the apertures A61, A62, and A63 and the display elements DE1, DE2, and DE3. In the illustrated example, the center line MC1 of the lens ML1 is located between the aperture edges AE5 and AE6 in the first direction X. That is, the center line MC1 overlaps the aperture A63 and the display element DE3 in plan view. That is, the center line MC1 intersects a portion of the partition 6 that extends in the first direction X.

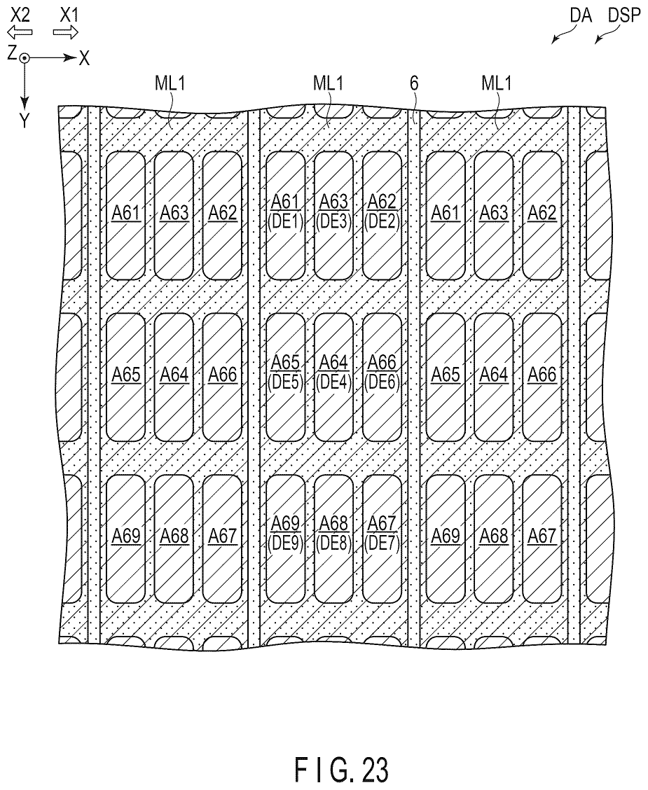

FIG. 23 is a schematic plan view showing an example of the layout of apertures A61 to A69. The display device DSP further comprises display elements DE7, DE8, and DE9. The display element DE7 has the same configuration as those of the display elements DE1 and DE4. That is, the display element DE7 includes a light emitting layer formed of a material exhibiting the same color as those of the display elements DE1 and DE4. The display element DE8 has the same configuration as those of the display elements DE2 and DE5. That is, the display element DE8 includes a light emitting layer formed of a material exhibiting the same color as those of the display elements DE2 and DE5. The display element DE9 has the same configuration as those of the display elements DE3 and DE6. That is, the display element DE9 includes a light emitting layer formed of a material exhibiting the same color as those of the display elements DE3 and DE6.

The color of light emitted from the display elements DE1, DE4, and DE7, the color of light emitted from the display elements DE2, DE5, and DE8, and the color of light emitted from the display elements DE3, DE6, and DE9 are different from one another.

The partition 6 further includes the apertures A67, A68, and A69 surrounded by the edge portion AE of the partition 6 (refer to FIG. 4). The aperture A67 overlaps the display element DE7. The aperture A68 overlaps the display element DE8. The aperture A69 overlaps the display element DE9. A row in which the apertures A61, A63, and A62 are repeatedly arranged in this order in the first direction X, a row in which the apertures A65, A64, and A66 are repeatedly arranged in this order in the first direction X, and a row in which the apertures A69, A68, and A67 are repeatedly arranged in this order in the first direction X are formed in the display area DA. These rows are arranged in the second direction Y.

That is, in the display area DA, a row in which the apertures A61, A65, and A69 are repeatedly arranged in this order in the second direction Y, a row in which the apertures A63, A64, and A68 are repeatedly arranged in this order in the second direction Y, and a row in which the apertures A62, A66, and A67 are repeatedly arranged in this order in the second direction Y are formed. These rows are arranged in the first direction X. The lens ML1 overlaps the apertures A61 to A69 and the display elements DE1 to DE9.

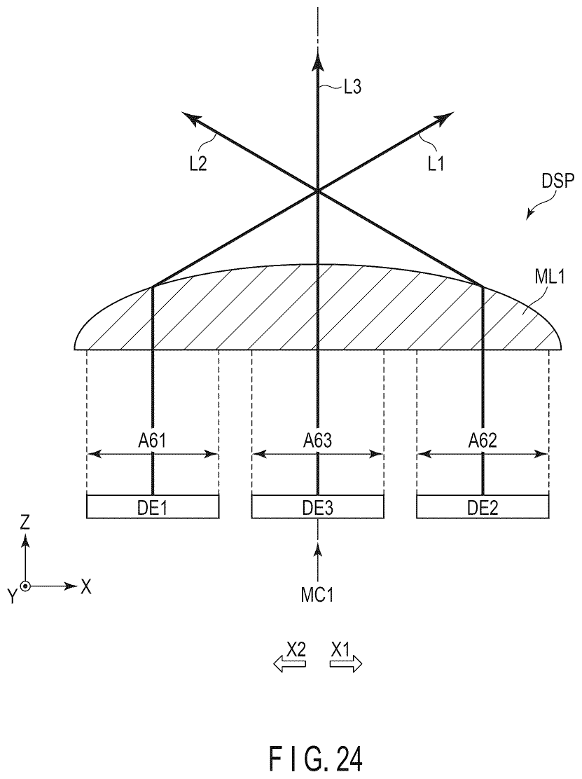

Next, effects of the present embodiment will be described with reference to FIG. 24. FIG. 24 is a diagram for explaining effects of the present embodiment.

As describe above, the light beam L1 emitted along the third direction Z from the display element DE1 that is located on the direction X2 side with respect to the center line MC1 is refracted at the interface between the lens ML1 and air and travels along a direction tilted from the third direction Z to the direction X1 side. In addition, the light beam L2 emitted along the third direction Z from the display element DE2 that is located on the direction X1 side with respect to the center line MC1 is refracted at the interface between the lens ML1 and air and travels along a direction tilted from the third direction Z to the direction X2 side.

Light beam L3 emitted along the third direction Z from the display element DE3 overlapping the center line MC1 is hardly refracted at the interface between the lens ML1 and air, and this light beam L3 travels along the third direction Z.

That is, a user in a traveling direction side of the light beam L1 can visually recognize light emitted from the display element DE1 but hardly visually recognizes light emitted from the display elements DE2 and DE3. That is, a user in a traveling direction side of the light beam L2 can visually recognize light emitted from the display element DE2 but hardly visually recognizes light emitted from the display elements DE1 and DE3. That is, a user in a traveling direction side of the light beam L3 can visually recognize light emitted from the display element DE3 but hardly visually recognizes light emitted from the display elements DE1 and DE2.

In the example shown in FIG. 23, a user in the direction X1 side with respect to the display device DSP can visually recognize light emitted from the display elements DE1, DE5, and DE9, but hardly visually recognizes light emitted from the display elements DE2, DE6, and DE7 and the display elements DE3, DE4, and DE8. A user in the direction X2 side with respect to the display device DSP can visually recognize light emitted from the display elements DE2, DE6, and DE7, but hardly visually recognizes light emitted from the display elements DE1, DE5, and DE9 and the display elements DE3, DE4, and DE8. A user in the third direction Z side with respect to the display device DSP can visually recognize light emitted from the display elements DE3, DE4, and DE8, but hardly visually recognizes light emitted from the display elements DE1, DE5, and DE9 and the display elements DE2, DE6, and DE7.

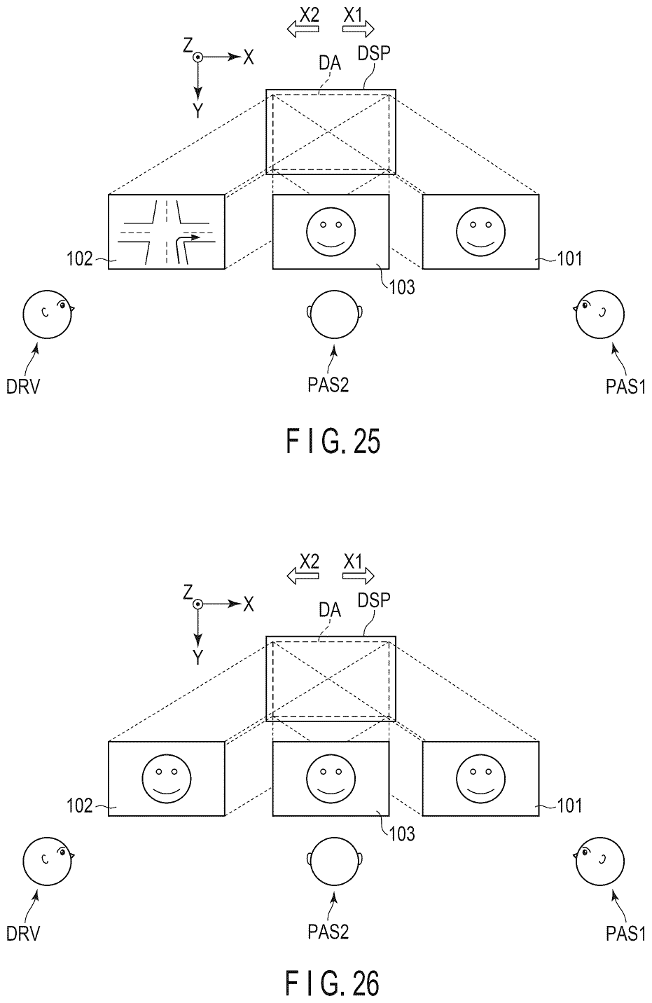

Next, a case where the display device DSP shown in FIG. 23 is mounted on a vehicle such as an automobile will be described. FIG. 25 to FIG. 27 are diagrams showing the display device DSP of the present embodiment that is mounted on a vehicle-mounted device. As an example, a case in which the display device DSP is located between a driver seat and a front passenger seat will be described.

When the display elements DE1 to DE9 in the display area DA are arranged in the layout shown in the example of FIG. 23, the passenger PAS1 in the front passenger seat sitting in the direction X1 side with respect to the display device DSP can visually recognize light emitted from the display elements DE1, DE5, and DE9. In contrast, the driver DRV sitting in the direction X2 side with respect to the display device DSP can visually recognize light emitted from the display elements DE2, DE6, and DE7. In contrast, a passenger PAS2 in a back seat sitting in the third direction Z side with respect to the display device DSP can visually recognize light emitted from the display elements DE3, DE4, and DE8. The display elements DE1, DE5, and DE9 are supplied with image signals for displaying an image for the passenger PAS1 in the front passenger seat, the display elements DE2, DE6, and DE7 are supplied with images signal for displaying an image for the driver DRV, and the display elements DE3, DE4, and DE8 are supplied with image signals for displaying an image for the passenger PAS2 in the back seat.

For example, in a case of a vehicle being driven, it is required that the display element DE1 is supplied with the same image signal as that of the display element DE4, the display element DE5 is supplied with the same image signal as that of the display element DE8, and the display element DE9 is supplied with the same image signal as that of the display element DE3. Then, as shown in FIG. 25, the passenger PAS1 in the front passenger seat and the passenger PAS2 in the back seat can visually recognize the display screen 101 and a display screen 103 on which the same image is displayed. In addition, the driver DRV can visually recognize the screen 102 on which an image different from the image visually recognized by the passenger PAS1 in the passenger seat and the passenger PAS2 in the back seat is displayed.

For example, in a case where the engine is in the off state, the display elements DE1, DE4, and DE7 are supplied with the same image signal, the display elements DE2, DE5, and DE8 are supplied with the same image signal, and the display elements DE3, DE6, and DE9 are supplied with the same image signal. Then, as shown in FIG. 26, the passenger PAS1 in the front passenger seat, the driver DRV, and the passenger PAS2 in the back seat can visually recognize the display screens 101, 102, and 103 on which the same image is displayed.

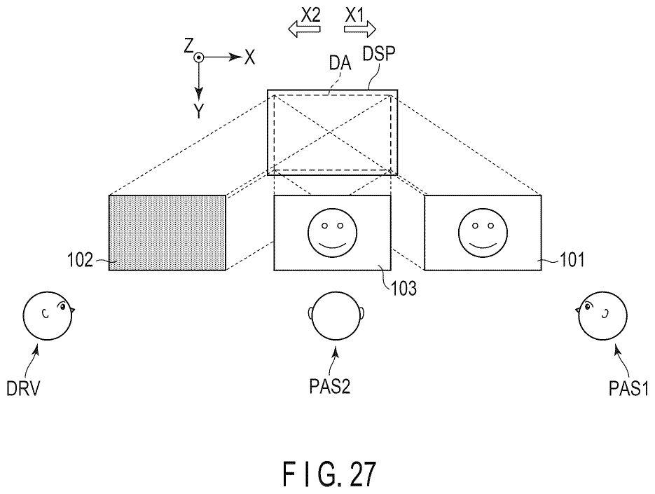

For example, when it is required that an image is hardly visually recognizable from the driver seat side during the vehicle driving, the display elements DE1, DE5, DE9 and the display elements DE3, DE4, and DE8 are supplied with the image signals, and the display elements DE2, DE6, and DE7 are not supplied with the image signals. Therefore, the display elements DE1, DE5, and DE9 and the display elements DE3, DE4, and DE8 are illuminated according to the image signals. In contrast, the display elements DE2, DE6, and DE7 are not illuminated. Then, as shown in FIG. 27, the passenger PAS1 in the front passenger seat and the passenger PAS2 in the back seat can visually recognize the display screens 101 and 103 on which an image is displayed, and the driver DRV can visually recognize the display screen 102, which is dark and an image is hardly displayed on.

When it is required that different images are visually recognizable by the respective passenger PAS1 in the passenger seat, driver DRV, and passenger PAS2 in the back seat, different image signals are supplied to the display elements DE1, DE5, and DE9, the display elements DE2, DE6, and DE7, and the display elements DE3, DE4, and DE8, respectively. Then, the passenger PAS1 in the front passenger seat, the driver DRV, and the passenger PAS2 in the back seat can visually recognize the display screens 101, 102, and 103 on which the respective different images are displayed, respectively.

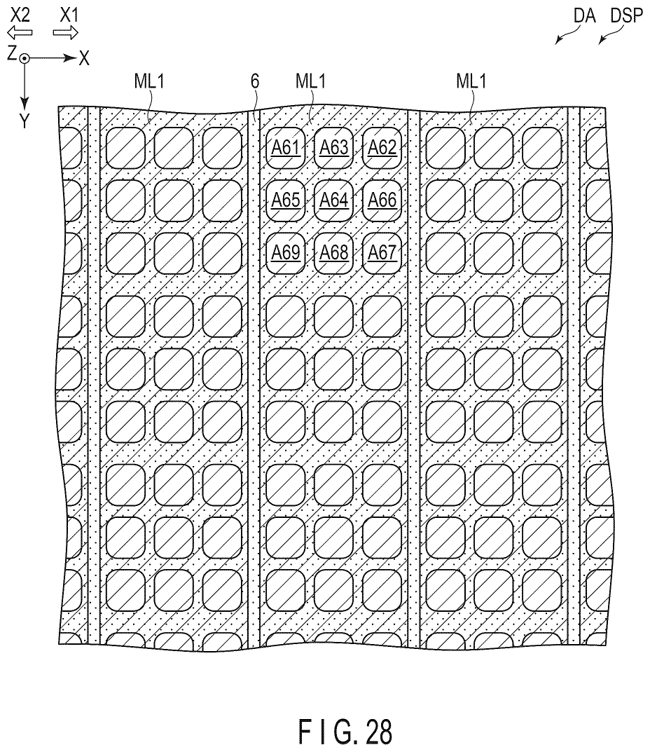

FIG. 28 is a schematic plan view showing another example of the layout of the apertures A61 to A69 shown in FIG. 23. The length along the second direction Y of each of the apertures A61 to A69 in FIG. 28 is approximately one-third the length along the second direction Y of each of the apertures A61 to A69 in FIG. 23. Thus, the number of the pixels of the display device DSP shown in FIG. 28 is approximately three times the number of the pixels of the display device DSP shown in FIG. 23. This configuration can increase the resolution of the display screen 101 visually recognizable by the passenger PAS1 in the front passenger seat, the resolution of the display screen 102 visually recognizable by the driver DRV, and the display screen 103 visually recognizable by the passenger PAS2 in the back seat.

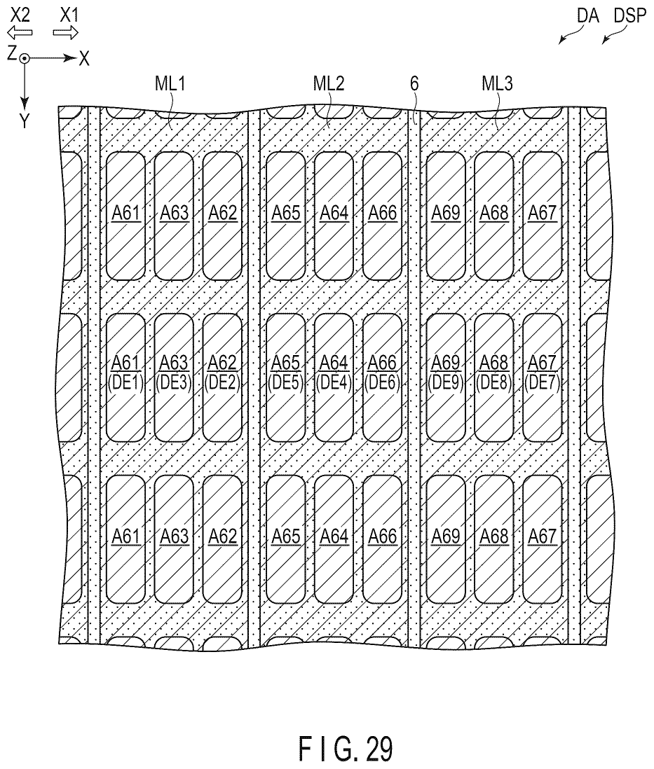

FIG. 29 is a schematic plan view showing another example of the layout of the apertures A61 to A69. A row in which the apertures A61, A63, A62, A65, A64, A66, A69, A68, and A67 are repeatedly arranged in this order in the first direction X is formed in the display area DA. This row is repeated in the second direction Y.

The display device DSP comprises the lenses ML1 and ML2 and a lens ML3. Each of the lenses ML1, ML2, and ML3 extends in the second direction Y. The lens ML1 overlaps the apertures A61, A62, and A63 and the display elements DE1, DE2, and DE3. The lens ML2 overlaps the apertures A64, A65, and A66 and the display elements DE4, DE5, and DE6. The lens ML3 overlaps the apertures A67, A68, and A69 and the display elements DE7, DE8, and DE9. The lenses ML2 and ML3 have the same configuration as that of the lens ML1. The lenses ML1, ML2, and ML3 are arranged in this order in the first direction X.

In the example shown in FIG. 29, a user in the direction X1 side with respect to the display device DSP can visually recognize light emitted from the display elements DE1, DE5, and DE9. A user in the direction X2 side with respect to the display device DSP can visually recognize light emitted from the display elements DE2, DE6, and DE7. A user in the third direction Z side with respect to the display device DSP can visually recognize light emitted from the display elements DE3, DE4, and DE8.

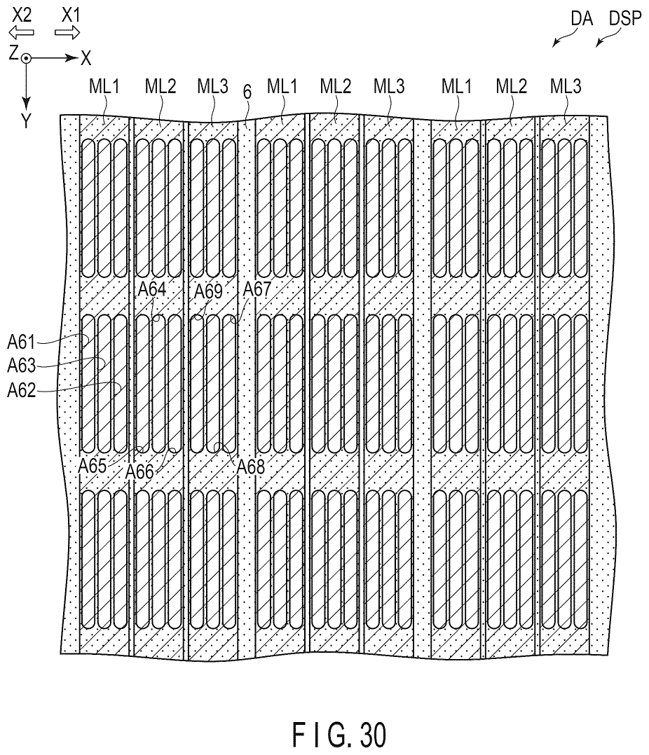

FIG. 30 is a schematic plan view showing another example of the layout of the apertures A61 to A69 shown in FIG. 29. The length along the first direction X of each of the apertures A61 to A69 in FIG. 30 is approximately one-third the length along the first direction X of each of the apertures A61 to A69 in FIG. 29. Thus, the number of the pixels of the display device DSP shown in FIG. 30 is approximately three times the number of the pixels of the display device DSP shown in FIG. 29. This configuration can increase the resolution of the display screen 101 visually recognizable by the passenger PAS1 in the front passenger seat, the resolution of the display screen 102 visually recognizable by the driver DRV, and the display screen 103 visually recognizable by the passenger PAS2 in the back seat.

All of the display devices that can be implemented by a person of ordinary skill in the art through arbitrary design changes to the display device described above as the embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device, comprising:
a substrate;
a first light emitting element and a second light emitting element, which are provided above the substrate and are adjacent to each other in a first direction;
a lower portion surrounding each of the first light emitting element and the second light emitting element;
an upper portion provided on the lower portion and including a first aperture overlapping the first light emitting element and a second aperture overlapping the second light emitting element, the first aperture and the second aperture being surrounded by an edge portion projecting relative to a side surface of the lower portion; and
a plurality of lenses having convex shapes projecting toward a side opposite to the substrate, wherein
the plurality of lenses include a first lens overlapping the first aperture and the second aperture.

2. The display device of claim 1, further comprising:
a third light emitting element provided above the substrate and adjacent to the first light emitting element in the first direction and adjacent to the second light emitting element in a second direction, the second direction intersecting the first direction, wherein
the lower portion surrounds the third light emitting element,
the upper portion further includes a third aperture surrounded by the edge portion and overlapping the third light emitting element, and
the first lens overlaps the third aperture.

3. The display device of claim 1, further comprising:
a third light emitting element provided above the substrate and provided between the first light emitting element and the second light emitting element, wherein
the lower portion surrounds the third light emitting element,
the upper portion further includes a third aperture surrounded by the edge portion and overlapping the third light emitting element, and
the first lens overlaps the third aperture.

4. The display device of claim 2, wherein
the first light emitting element, the second light emitting element, and the third light emitting element include light emitting layers formed of materials emitting light in colors different from one another.

5. The display device of claim 2, further comprising:
a fourth light emitting element provided above the substrate and adjacent to the third light emitting element in the second direction;
a fifth light emitting element provided above the substrate, adjacent to the fourth light emitting element in the first direction and adjacent to the first light emitting element in the second direction;
a sixth light emitting element provided above the substrate, adjacent to the fourth light emitting element in the first direction and adjacent to the fifth light emitting element in the second direction, wherein
the lower portion surrounds each of the fourth light emitting element, the fifth light emitting element, and the sixth light emitting element,
the upper portion further includes a fourth aperture overlapping the fourth light emitting element, a fifth aperture overlapping the fifth light emitting element, and a sixth aperture overlapping the sixth light emitting element that are surrounded by the edge portion, and
the first lens overlaps the fourth aperture, the fifth aperture, and the sixth aperture.

6. The display device of claim 2, further comprising:
a fourth light emitting element provided above the substrate and adjacent to the first light emitting element in the first direction;
a fifth light emitting element provided above the substrate and adjacent to the fourth light emitting element in the first direction; and
a sixth light emitting element provided above the substrate, adjacent to the fourth light emitting element in the first direction and adjacent to the fifth light emitting element in the second direction, wherein
the lower portion surrounds each of the fourth light emitting element, the fifth light emitting element, and the sixth light emitting element,
the upper portion further includes a fourth aperture overlapping the fourth light emitting element, a fifth aperture overlapping the fifth light emitting element, and a sixth aperture overlapping the sixth light emitting element that are surrounded by the edge portion, and
the plurality of lenses include a second lens overlapping the fourth aperture, the fifth aperture, and the sixth aperture.

7. The display device of claim 2, further comprising:
a fourth light emitting element provided above the substrate and adjacent to the first light emitting element in the second direction;
a fifth light emitting element provided above the substrate, adjacent to the fourth light emitting element in the first direction and adjacent to the third light emitting element in the second direction; and
a sixth light emitting element provided above the substrate, adjacent to the fourth light emitting element in the first direction and adjacent to the fifth light emitting element in the second direction, wherein
the lower portion surrounds each of the fourth light emitting element, the fifth light emitting element, and the sixth light emitting element,
the upper portion further includes a fourth aperture overlapping the fourth light emitting element, a fifth aperture overlapping the fifth light emitting element, and a sixth aperture overlapping the sixth light emitting element that are surrounded by the edge portion, and
the plurality of lenses include a second lens overlapping the fourth aperture and a third lens overlapping the fifth aperture and the sixth aperture.

8. The display device of claim 7, wherein
a cross-sectional shape along the first direction and a cross-sectional shape along the second direction of each of the plurality of lenses have convex shapes projecting toward the side opposite to the substrate.

9. The display device of claim 2, wherein
each of the plurality of lenses has a center line parallel to the second direction, and
the center line overlaps the upper portion.

10. The display device of claim 3, wherein
each of the plurality of lenses has a center line parallel to a second direction, the second direction intersecting the first direction, and
the center line intersects the upper portion.

11. The display device of claim 5, wherein
the first light emitting element and the fourth light emitting element include light emitting layers formed of materials emitting light in first colors that are equivalent to each other,
the second light emitting element and the fifth light emitting element include light emitting layers formed of materials emitting light in second colors that are equivalent to each other,
the third light emitting element and the sixth light emitting element include light emitting layers formed of materials emitting light in third colors that are equivalent to each other, and
the first color, the second color, and the third color are different from one another.

12. The display device of claim 1, wherein
the first light emitting element includes a light emitting layer formed of a material emitting green-colored light or blue-colored light.

13. The display device of claim 2, wherein
the first aperture, the second aperture, and the third aperture have areas different from one another.

14. The display device of claim 3, wherein
the first aperture, the second aperture, and the third aperture have areas equivalent to one another.

15. The display device of claim 1, wherein
each of the plurality of lenses has a first lens edge and a second lens edge that are parallel to a second direction, the second direction intersecting the first direction, and
the display device further comprises a light-shielding layer overlapping the first lens edge and the second lens edge.

16. The display device of claim 15, wherein
the first lens edge and the second lens edge overlap the upper portion in plan view.

17. The display device of claim 1, wherein
each of the plurality of lenses has a flat surface at an apex portion.

18. The display device of claim 1, further comprising:
a first organic insulating layer provided on the first light emitting element;
a sealing layer provided on the first organic insulating layer; and
a second organic insulating layer provided between the sealing layer and the plurality of lenses, wherein
the second organic insulating layer is thicker than the first organic insulating layer.

19. The display device of claim 18, further comprising:
a color filter provided between the sealing layer and the second organic insulating layer.

20. The display device of claim 1, wherein
the plurality of lenses are formed of transparent resin materials.
